(19) United States
(12) Patent Application Publication
(10) Pub. No.: US 2022/0272873 A1
(43) Pub. Date: Aug. 25, 2022

(54) WATER-COOLED AND FLOW-CONTROLLED HEAT DISSIPATION SYSTEM USED IN CABINET AND CONTROL METHOD THEREOF

(71) Applicant: TAIWAN MICROLOOPS CORP., New Taipei City (TW)

(72) Inventor: Chun-Hung LIN, New Taipei City (TW)

(21) Appl. No.: 17/184,257

(22) Filed: Feb. 24, 2021

(51) Int. Cl. H05K 7/20; F28F 27/02; G05D 23/19; G05D 7/06; F28F 9/02

(52) U.S. Cl. CPC H05K 7/20781; F28F 27/02; G05D 23/1934; G05D 7/0688; H05K 7/20281; H05K 7/20272; F28F 9/0275; F28F 2250/08

(57) ABSTRACT

This disclosure relates to a water-cooled and flow-controlled heat dissipation system used in a cabinet and a control method thereof. The heat dissipation system includes a water supply apparatus, multiple water blocks, a pipe assembly, multiple throttles, and a control unit. The pipe assembly has a distribution pipe, a converging pipe, multiple inlet pipes, and multiple outlet pipes. One end of the distribution pipe and one end of the converging pipe are communicated with the water supply apparatus. Each inlet pipe has two ends communicated with the distribution pipe and to each water block respectively. Each outlet pipe has two ends communicated with the converging pipe and to each water blocks. Each throttle is installed in each inlet pipe, each outlet pipe, or each water block. The control unit is electrically connected to the throttles and controls the opening degree of each throttle.

### BACKGROUND OF THE INVENTION

### Field of the Invention

This disclosure relates to a water-cooled and flow-controlled heat dissipation system and in particular relates to a water-cooled and flow-controlled heat dissipation system used in a cabinet and a control method thereof.

### Description of Related Art

The related water-cooled heat dissipation system applied to the server cabinet primarily uses a main pump to deliver the working fluid from the water box to the water blocks corresponding to the heat sources inside different servers in a distributed way. Thus, the effect of water cooling can be achieved. However, the flow rate of the working fluid is always affected by the pipe length when it flows by means of the pipe connection. For example, the longer the pipe is, the slower the flow rate becomes.

However, the servers in the cabinet are usually arranged in an up and down configuration or in a vertical direction and the distance between the uppermost server and the lowermost one is the longest. Consequently, the flow rates obtained by the two above-mentioned servers are different because of the above-mentioned pipe connection. As a result, the heat dissipation or cooling effect becomes uneven. If the minimal heat dissipation or cooling effect is required, the power of the pump needs to be increased, which results in waste and higher cost of energy.

In view of this, the inventor pays attention to research with the application of related theory and tries to improve and overcome the above disadvantages regarding the related art, which becomes the improvement target of the inventor.

### SUMMARY OF THE INVENTION

This disclosure provides a water-cooled and flow-controlled heat dissipation system used in a cabinet and a control method thereof. The heat dissipation system makes the working fluids in each water blocks have uniform bypass flow rate such that the heat dissipation system may have the function of uniform flows, heat dissipation, and cooling.

In an embodiment of this disclosure, this disclosure provides a water-cooled and flow-controlled heat dissipation system used in a cabinet in which the cabinet has a plurality of servers and a plurality of heat generating components installed in each server. The water-cooled and flow-controlled heat dissipation system includes a water supply apparatus, a plurality of water blocks, a pipe assembly, a plurality of throttles, and a control unit. Each of the water blocks is installed in each server and thermally attached to each of the heat generating components. The pipe assembly has a distribution pipe, a converging pipe, a plurality of inlet pipes, and a plurality of outlet pipes. One end of the distribution pipe and one end of the converging pipe are communicated with the water supply apparatus. One end of each of the inlet pipes is communicated with the distribution pipe and the other end of each of the inlet pipes is communicated with each water block. One end of each of the outlet pipes is communicated with the converging pipe and the other end of each of the outlet pipes is communicated with each water block. Each of throttles is installed in each inlet pipe, in each outlet pipe, or in each water block. The control unit is electrically connected to the throttles and is used to control the opening degree of each throttle.

In an embodiment of this disclosure, this disclosure provides a control method of a water-cooled and flow-controlled heat dissipation system. The control method includes the steps of (a) providing a cabinet which has a plurality of servers and a plurality of heat generating components installed in each servers, (b) providing a plurality of water blocks, each of which is installed in each servers and thermally attached to each heat generating component, (c) providing a water supply apparatus and a pipe assembly, wherein the pipe assembly has a distribution pipe, a converging pipe, a plurality of inlet pipes, and a plurality of outlet pipes, wherein one end of the distribution pipe and one end of the converging pipe are communicated with the water supply apparatus, wherein one end of each of the inlet pipes is communicated with the distribution pipe and the other end of the each of the inlet pipes is communicated with each water block, wherein one end of each of the outlet pipes is communicated with the converging pipe and the other end of the each of the outlet pipes is communicated with each water block, (d) providing a plurality of throttles, each of which is installed in each inlet pipe, in each outlet pipe, or in each water block, (e) providing a plurality of flow sensors, wherein each of the flow sensors is installed in each inlet pipe, in each outlet pipe, or in each water block, wherein the each of the flow sensors is used to sense flowrate and generate a flowrate signal, and (f) providing a control unit which is electrically connected to the throttles, wherein the control unit receives the flowrate signal less than a predetermined flowrate to increase the opening degree of the corresponding throttle and receives the flowrate signal greater than the predetermined flowrate to decrease the opening degree of the corresponding throttle.

Based on the above description, the transport power of the working fluid in each water block may have uniform bypass flow rate to stabilize the flow rate and the flow speed of the working fluid in each water block. Therefore, beneficial effects of uniform flows, heat dissipation, and cooling may be achieved.

### BRIEF DESCRIPTION OF DRAWINGS

FIG. 1 is a perspective schematic view of the water-cooled and flow-controlled heat dissipation system of this disclosure;

FIG. 2 is a cross-sectional view of the water-cooled and flow-controlled heat dissipation system of this disclosure;

FIG. 3 is a block diagram of the water-cooled and flow-controlled heat dissipation system of this disclosure; and

FIG. 4 is a flow chart of the control method of a water-cooled and flow-controlled heat dissipation system of this disclosure.

### DETAILED DESCRIPTION OF THE INVENTION

The detailed description and technical details of this disclosure are explained below with reference to accompanying figures. However, the accompanying figures are for reference and explanation only, but not to limit the scope of this disclosure.

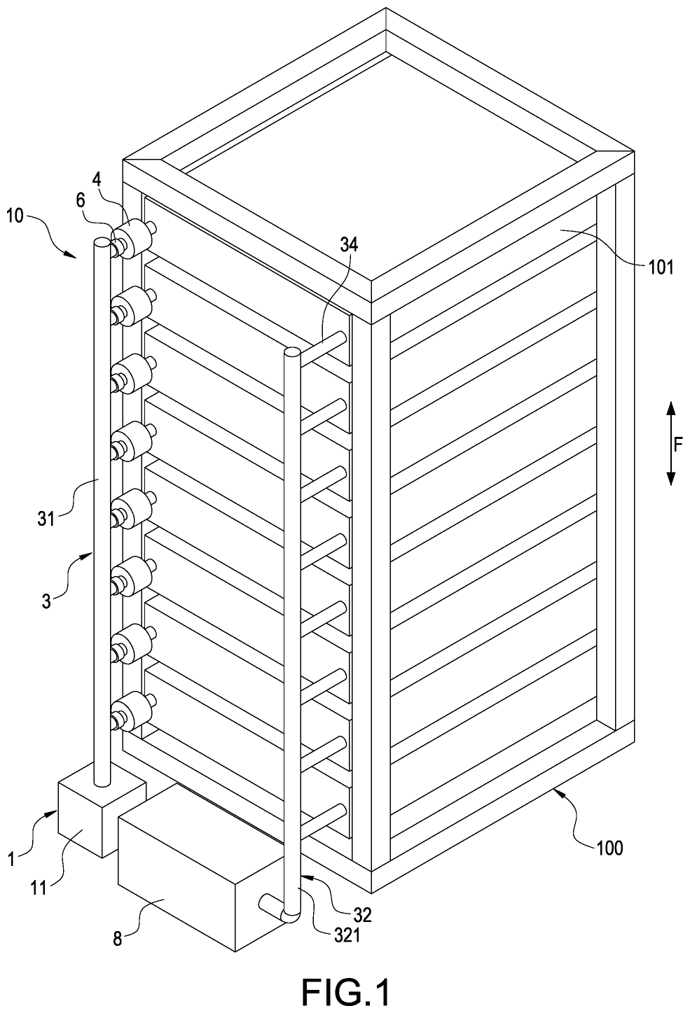

Please refer to FIGS. 1 to 4. This disclosure provides a water-cooled and flow-controlled heat dissipation system used in a cabinet and a control method thereof. The water-cooled and flow-controlled heat dissipation system 10 includes a water supply apparatus 1, a plurality of water blocks 2, a pipe assembly 3, a plurality of throttles 4, and a control unit 5.

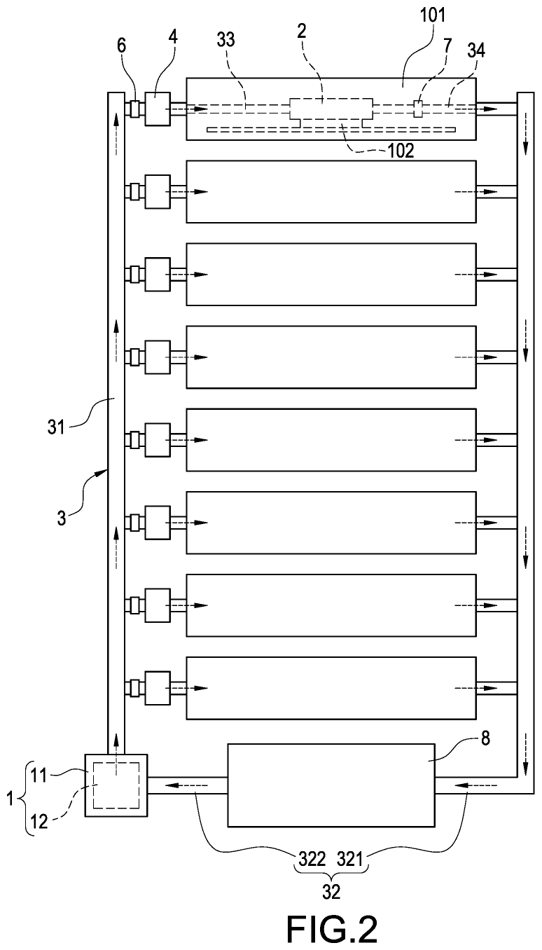

As shown in FIGS. 1 and 2, the cabinet 100 has a plurality of servers 101 and a plurality of heat generating components 102 installed in each server 101. The heat generating components 102 may be CPUs, display cards, etc. In this embodiment, the servers 101 are stacked in an up and down configuration, but not limited to this.

As shown in FIGS. 1-3, the water supply apparatus 1 has a water box 11 and a pump 12 communicated with the water box 11. The water box 11 is used to provide the working fluid like water for heat dissipation or cooling. In this embodiment, the pump 12 is installed in the water box 11, but not limited to this.

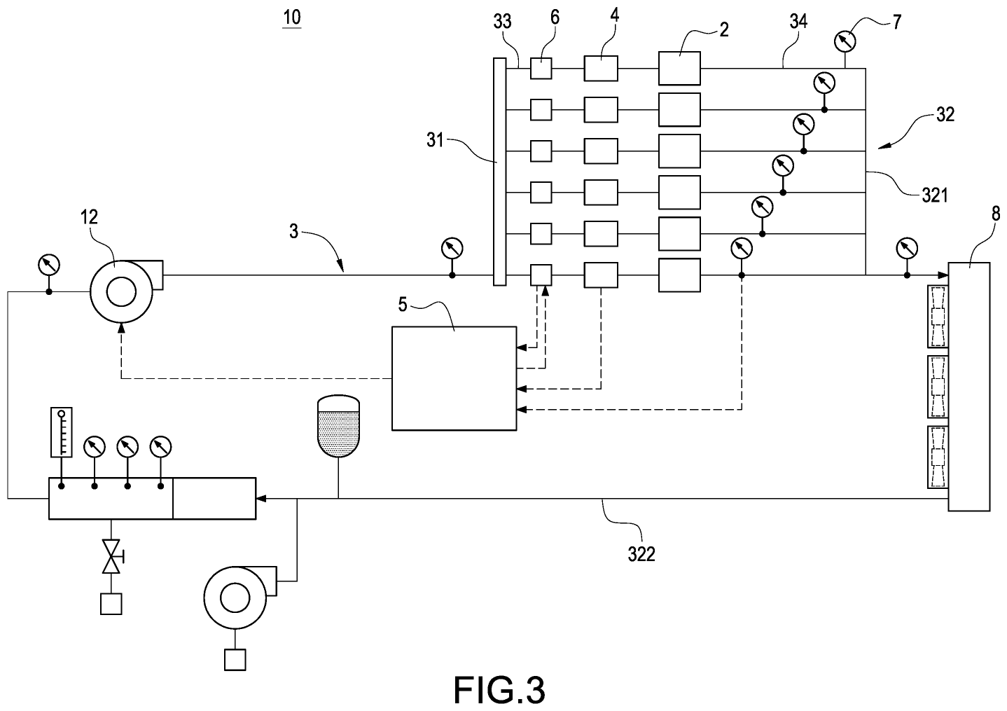

As shown in FIGS. 2 and 3, each of the water blocks 2 is installed in each server 101 and thermally attached to each heat generating component 102. The water blocks 2 are used to facilitate heat dissipation of the heat generating components 102.

As shown in FIGS. 1 to 3, the pipe assembly 3 has a distribution pipe 31, a converging pipe 32, a plurality of inlet pipes 33, and a plurality of outlet pipes 34. One end of the distribution pipe 31 and one end of the converging pipe 32 are communicated with the water box 11 of the water supply apparatus 1. One end of each of the inlet pipes 33 is communicated with the distribution pipe 31 and the other end of each of the inlet pipes 33 is communicated with each water block 2. One end of each of the outlet pipes 34 is communicated with the converging pipe 32 and the other end of each of the outlet pipes 34 is communicated with each water block 2. The pump 12 is used to pump (or drive) the working fluid in the water box 11 to flow to the converging pipe 32 through the distribution pipe 31, the inlet pipes 33, and the outlet pipes 34 in sequence to further enhance the heat dissipation of the heat generating components 102 in the servers 101.

As shown in FIGS. 1 to 3, each of the throttles 4 in this embodiment is installed in each inlet pipe 33, but not limited to this. In some other embodiments, each of the throttles 4 may be installed in each outlet pipe 34, or in each water block 2. Each of the throttles 4 generates an opening degree signal based on the opening degree thereof.

As shown in FIG. 3, the control unit 5 is electrically connected to the throttles 4 and to the pump 12. The control unit 5 may control the opening degree of each throttle 4 and the rotating speed of the pump 12.

As shown in FIGS. 1 to 3, the water-cooled and flow-controlled heat dissipation system 10 of this disclosure further includes a plurality of flowrate sensors 6. In this embodiment, each of the flowrate sensors 6 is installed in each inlet pipe 33, but not limited to this. In some other embodiments, each of the flowrate sensors 6 may be installed in each outlet pipe 34 or each water block 2. Each of the flowrate sensors 6 is used to sense a flowrate and generate a flowrate signal.

As shown in FIGS. 2 and 3, the water-cooled and flow-controlled heat dissipation system 10 further includes a plurality of temperature sensors 7. In this embodiment, each of the temperature sensors 7 is installed in each outlet pipe 34, but not limited to this. In some other embodiments, each of the temperature sensors 7 may be installed in each inlet pipe 33, in each water block 2, or on each heat generating component 102. Each of the temperature sensors 7 is used to sense a temperature and generate a temperature signal.

The control unit 5 receives each temperature signal and each flowrate signal and then controls the opening degree of each throttle 4. The control unit 5 receives each flowrate signal and each opening degree signal and then controls the rotating speed of the pump 12.

As shown in FIGS. 1 to 3, the water-cooled and flow-controlled heat dissipation system 10 of this disclosure further includes a cooling unit 8. The converging pipe 32 is arranged as a first converging pipe 321 and a second converging pipe 322. One end of the first converging pipe 321 is communicated with the outlet pipes 34 and the other end of the first converging pipe 321 is communicated with the cooling unit 8. One end of the second converging pipe 322 is communicated with the cooling unit 8 and the other end of the second converging pipe 322 is communicated with the water box 11. The cooling unit 8 is used to cool the working fluid flowed to the first converging pipe 321. The working fluid flows to the water box 11 through the second converging pipe 322. In this way, the working fluid may be circulated and reused. The cooling unit 8 includes the heat dissipation components such as the cooling fins, the vapor chambers, the fans, and the cooling chips, etc.

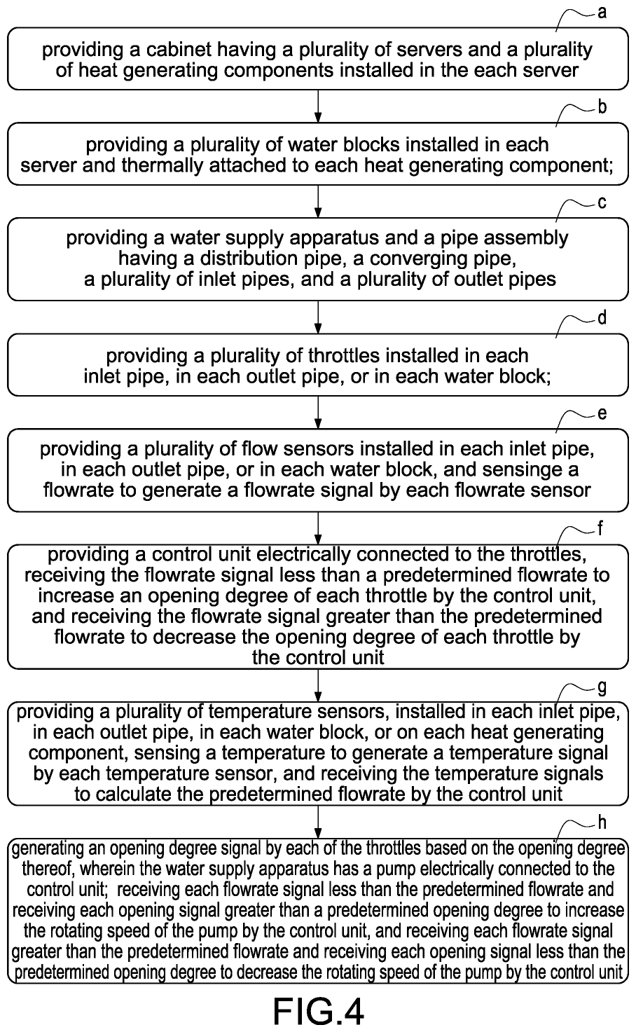

As shown in FIG. 4, the control method of a water-cooled and flow-controlled heat dissipation system 10 of this disclosure includes the steps (a)-(h) and is described below. First, as shown in the step (a) of FIG. 4 and in FIGS. 1 and 2, a cabinet 100 is provided and the cabinet 100 has a plurality of servers 101 and a plurality of heat generating components 102 installed in each server 101.

Second, as shown in the step (b) of FIG. 4 and in FIGS. 2 and 3, a plurality of water blocks 2 are provided, each of the water blocks 2 is installed in each server 101 and thermally attached to each heat generating component 102.

Third, as shown in the step (c) of FIG. 4 and in FIGS. 1 to 3, a water supply apparatus 1 and a pipe assembly 3 are provided in which the pipe assembly 3 has a distribution pipe 31, a converging pipe 32, a plurality of inlet pipes 33, and a plurality of outlet pipes 34. One end of the distribution pipe 31 and one end of the converging pipe 32 are communicated with the water supply apparatus 1. One end of each of the inlet pipes 33 is connected to the distribution pipe 31 and the other end of each of the inlet pipes 33 is communicated with each water block 2. One end of each of the outlet pipes 34 is communicated with the converging pipe 32 and the other end of each of the outlet pipes 34 is communicated with each water block 2.

Fourth, as shown in the step (d) of FIG. 4 and in FIGS. 1 to 3, a plurality of throttles 4 are provided, each of which is installed in each inlet pipe 33, in each outlet pipe 34, or in each water block 2.

Fifth, as shown in the step (e) of FIG. 4 and in FIGS. 1 to 3, a plurality of flowrate sensors 6 are provided. Each of the flowrate sensors 6 is installed in each inlet pipe 33, each outlet pipe 34, or each water block 2. Each of the flowrate sensors 6 is used to sense a flowrate and generate a flowrate signal.

Sixth, as shown in the step (f) of FIG. 4 and in FIG. 3, a control unit 5 is provided, which is electrically connected to the throttles 4. The control unit 5 receives the flowrate signal less than a predetermined flowrate to increase the opening degree of each throttle 4 and receives the flowrate signal greater than the predetermined flowrate to decrease the opening degree of each throttle 4.

In this way, the transport power of the working fluid in each water blocks 21 may have uniform bypass flow rate to stabilize the flow rate and the flow speed of the working fluid in each water block 21. Therefore, beneficial effects of uniform flows, heat dissipation, and cooling may be achieved.

Seventh, as shown in the step (g) of FIG. 4 and with reference also to FIGS. 2 and 3, a plurality of temperature sensors 7 are provided. Each of the temperature sensors 7 is installed in each inlet pipe 33, each outlet pipe 34, each water block 2, or on each heat generating component 102. Each of the temperature sensors 7 is used to sense a temperature and generate a temperature signal. The control unit 5 receives the temperature signals to calculate the predetermined flowrate.

Therefore, the working fluid in thermal contact with the heat generating component 102 having higher temperature may obtain greater bypass flow such that the working fluid has greater flow rate and greater flow speed to rapidly transfer the heat generated from the heat generating component 102 to the cooling unit 8. Consequently, efficiency of heat dissipation of the water-cooled and flow-controlled heat dissipation system 10 may be increased.

Eighth, as shown in the step (h) of FIG. 4 and with reference also to FIGS. 2 and 3, the water supply apparatus 1 has a pump 12 which is electrically connected to the control unit 5, an opening degree signal is generated by each of the throttles 4 based on the opening degree thereof. The control unit 5 receives each flowrate signal less than the predetermined flowrate and receives each opening degree signal greater than a predetermined opening degree to increase the rotating speed of the pump 12; the control unit 5 receives each flowrate signal greater than the predetermined flowrate and receives each opening degree signal less than the predetermined opening degree to decrease the rotating speed of the pump 12.

Thus, the flow rate of the working fluid is adjusted through the opening degree of each throttle 4 until the flowrate signal reaches the predetermined flowrate. If the opening degree of each throttle 4 reaches the limits (e.g., the opening degree of the throttle 4 cannot be increased or decreased any more), the rotating speed of the pump 12 is adjusted such that each flowrate signal reaches the predetermined flowrate. Further, the efficiency of heat dissipation and cooling of the water-cooled and flow-controlled heat dissipation system 10 may be stabilized.

Although this disclosure has been described with reference to the foregoing embodiment, it will be understood that the disclosure is not limited to the details thereof. Various equivalent variations and modifications can still occur to those skilled in this art in view of the teachings of this disclosure. Thus, all such variations and equivalent modifications are also embraced within the scope of this disclosure as defined in the appended claims.

What is claimed is:

1. A water-cooled and flow-controlled heat dissipation system used in a cabinet comprising a plurality of servers and a plurality of heat generating components installed in each server, the water-cooled and flow-controlled heat dissipation system comprising:
a water supply apparatus;
a plurality of water blocks, installed in each server respectively and thermally attached to each heat generating component;
a pipe assembly, comprising a distribution pipe, a converging pipe, a plurality of inlet pipes, and a plurality of outlet pipes, wherein one end of the distribution pipe and one end of the converging pipe are communicated with the water supply apparatus, one end of each of the inlet pipes is communicated with the distribution pipe and the other end of each of the inlet pipes is communicated with each water block, one end of each of the outlet pipes is communicated with the converging pipe and the other end of each of the outlet pipes is communicated with each water block;
a plurality of throttles, installed respectively in each inlet pipe, in each outlet pipe, or in each water block; and
a control unit, electrically connected to the throttles and controlling an opening degree of each throttle.

2. The water-cooled and flow-controlled heat dissipation system according to claim 1, further comprising: a plurality of flowrate sensors, installed respectively in each inlet pipe, in each outlet pipe, or in each water block, wherein each of the flowrate sensors senses a flowrate to generate a flowrate signal, and the control unit receives the flowrate signal to control the opening degree of each throttle.

3. The water-cooled and flow-controlled heat dissipation system according to claim 2, further comprising: a plurality of temperature sensors, installed respectively in each inlet pipe, in each outlet pipe, in each water block, or on each heat generating component, wherein each of the temperature sensors senses a temperature to generate a temperature signal, and the control unit receives the temperature signal to control the opening degree of each throttle.

4. The water-cooled and flow-controlled heat dissipation system according to claim 3, wherein the water supply apparatus comprises a water box and a pump communicated with the water box, one end of the distribution pipe and one end of the converging pipe are communicated with the water box, the pump drives a working fluid in the water box to flow to the converging pipe through the distribution pipe, the inlet pipes, and the outlet pipes in sequence.

5. The water-cooled and flow-controlled heat dissipation system according to claim 4, wherein the control unit is electrically connected to the pump, each of the throttles generates an opening degree signal based on the opening degree thereof, the control unit receives each flowrate signal and each opening degree signal to control the rotating speed of the pump.

6. The water-cooled and flow-controlled heat dissipation system according to claim 4, further comprising: a cooling unit, wherein the converging pipe comprises a first converging pipe and a second converging pipe, one end of the first converging pipe is communicated with the outlet pipes and the other end of the first converging pipe is communicated with the cooling unit, one end of the second converging pipe is communicated with the cooling unit and the other end of the second converging pipe is communicated with the water box.

7. The water-cooled and flow-controlled heat dissipation system according to claim 1, wherein the servers are stacked in an up and down configuration.

8. A control method of a water-cooled and flow-controlled heat dissipation system, the control method comprising:
(a) providing a cabinet comprising a plurality of servers and a plurality of heat generating components installed in each server;
(b) providing a plurality of water blocks installed in each server and thermally attached to each heat generating component;
(c) providing a water supply apparatus and a pipe assembly comprising a distribution pipe, a converging pipe, a plurality of inlet pipes, and a plurality of outlet pipes, wherein one end of the distribution pipe and one end of the converging pipe are communicated with the water supply apparatus, one end of each of the inlet pipes is communicated with the distribution pipe and the other end of each of the inlet pipes is communicated with each water block, one end of each of the outlet pipes is communicated with the converging pipe and the other end of each of the outlet pipes is communicated with each water block;
(d) providing a plurality of throttles installed respectively in each inlet pipe, in each outlet pipe, or in each water block;
(e) providing a plurality of flowrate sensors installed respectively in each inlet pipe, in each outlet pipe, or in each water block, and sensing a flowrate to generate a flowrate signal by each flowrate sensor; and
(f) providing a control unit electrically connected to the throttles, receiving the flowrate signal less than a predetermined flowrate to increase an opening degree of each throttle by the control unit, and receiving the flowrate signal greater than the predetermined flowrate to decrease the opening degree of each throttle by the control unit.

9. The control method of the water-cooled and flow-controlled heat dissipation system according to claim 8, further comprising a step (g) after the step (f), the step (g) comprising: providing a plurality of temperature sensors installed respectively in each inlet pipe, in each outlet pipe, in each water block, or on each heat generating component, sensing a temperature to generate a temperature signal by each temperature sensor, and receiving the temperature signals to calculate the predetermined flowrate by the control unit.

10. The control method of a water-cooled and flow-controlled heat dissipation system according to claim 9, further comprising a step (h) after the step (g), the step (h) comprising: generating an opening degree signal by each of the throttles based on the opening degree thereof, wherein the water supply apparatus comprises a pump electrically connected to the control unit; receiving each flowrate signal less than the predetermined flowrate and receiving each opening signal greater than a predetermined opening degree to increase the rotating speed of the pump by the control unit, and receiving each flowrate signal greater than the predetermined flowrate and receiving each opening signal less than the predetermined opening degree to decrease the rotating speed of the pump by the control unit.
